(19) United States
(12) Patent Application Publication
(10) Pub. No.: US 2008/0048315 A1
(43) Pub. Date: Feb. 28, 2008

(54) Electronic Device and Package Used for the Same

(75) Inventors: Natsuyo Nagano, Osaka (JP); Takashi Ogura, Kyoto (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Sanyo Electric Co., Ltd., Moriguchi-shi (JP)

(21) Appl. No.: 11/664,108

(22) PCT Filed: Sep. 8, 2005
(86) PCT No.: PCT/JP05/16493

§ 371 Date: Mar. 29, 2007

(30) Foreign Application Priority Data
Sep. 30, 2004 (JP) 2004-286398

(51) Int. Cl. H03H 9/05; H01L 23/15

(52) U.S. Cl. 257/723; 333/132; 257/E23.009

(57) ABSTRACT

[PROBLEM ] To provide a laminate ceramic electronic device applicable to two types of design specifications by using a common package.

[SOLUTION A laminate ceramic electronic device of the present invention has filter chips 2, 3 for transmission and reception mounted therein. A wiring pattern 7, which connects an input terminal A of the transmission filter chip 2 with a transmission side signal terminal Tx in a first arrangement, has two branch wiring portions 72, 73 extending from the transmission side signal terminal Tx toward the input terminal A of the transmission filter chip 2 in the first arrangement and toward an output terminal D of the reception filter chip 3 in a second arrangement. A wiring pattern 8, which connects the output terminal D of the reception filter chip 3 with a reception side signal terminal Rx in the first arrangement, has two branch wiring portions 82, 83 extending from the reception side signal terminal Rx toward the output terminal D of the reception filter chip 3 in the first arrangement and toward the input terminal A of the transmission filter chip 2 in the second arrangement.

### TECHNICAL FIELD

The present invention relates to a laminate ceramic electronic device in which one or more circuit chips are mounted on a substrate formed by laminating a plurality of ceramic layers, and to a package used for the laminate ceramic electronic device. The invention also relates to an electronic device in which one or more circuit chips are mounted on a substrate including one or more substrate layers, and to a package used for the electronic device.

### BACKGROUND ART

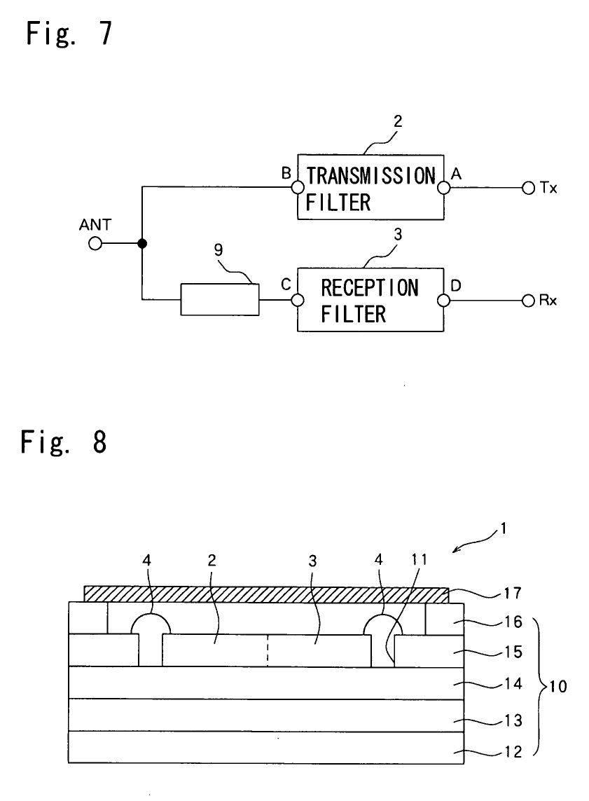

As shown in FIG. 7, an antenna duplexer provided in a portable telephone or the like includes an antenna terminal ANT to be connected to an antenna, a transmission side signal terminal Tx to be connected to a transmitting circuit, and a reception side signal terminal Rx to be connected to a receiving circuit. The antenna terminal ANT is connected to the transmission side signal terminal Tx via a transmission filter chip 2 including a surface acoustic wave device, and connected to the reception side signal terminal Rx via a reception filter chip 3 including a surface acoustic wave device (see Patent Document 1).

A phase-matching strip line 9 for phase rotation is interposed between the antenna terminal ANT and the reception filter chip 3 to match the phases between the transmission filter chip 2 and the reception filter chip 3 (see Patent Document 2).

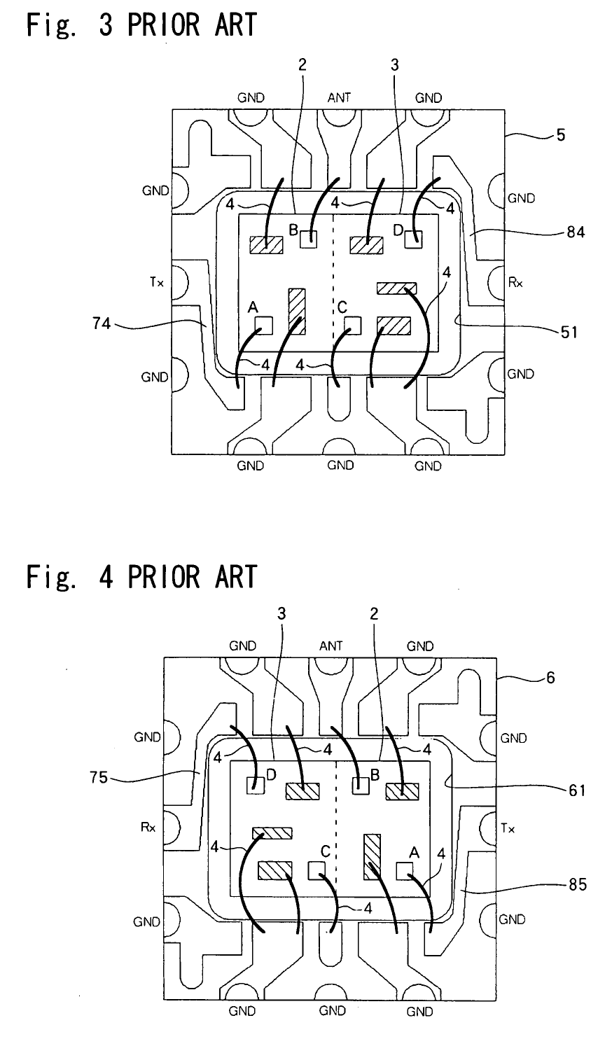

FIG. 3 shows the construction of the antenna duplexer enclosed in a package. A laminate ceramic package 5 is constructed by recessing a surface of a substrate formed by laminating a plurality of ceramic layers to provide a cavity 51. The transmission filter chip 2 and the reception filter chip 3 are arranged on the bottom surface of the cavity 51 in a side-by-side relationship. FIG. 3 is a plan view of the package 5 where the top ceramic layer is not shown.

An input terminal A and an output terminal B are disposed as signal terminals on a surface of the transmission filter chip 2, and an input terminal C and an output terminal D are disposed as signal terminals on a surface of the reception filter chip 3. These signal terminals are respectively coupled via wires 4 with a plurality of wiring patterns formed on the substrate and around the cavity 51.

The antenna terminal ANT, transmission side signal terminal Tx, reception side signal terminal Rx, and a plurality of ground terminals GND, which serve as external connection terminals, are respectively formed as side electrodes on a side surface of the substrate. These terminals are respectively connected via the wiring patterns and the wires 4 to the corresponding signal terminals of the transmission filter chip 2 and reception filter chip 3.

The transmission side signal terminal Tx is connected via a transmission side input signal wiring pattern 74 and wire 4 with the input terminal A of the transmission filter chip 2, and the reception side signal terminal Rx is connected via a reception side output signal wiring pattern 84 and wire 4 with the output terminal D of the reception filter chip 3.

FIG. 4 shows the construction of another antenna duplexer enclosed in a package. A package 6 is constructed by recessing a surface of a substrate formed by laminating a plurality of ceramic layers to provide a cavity 61. The transmission filter chip 2 and the reception filter chip 3 are arranged on the bottom surface of the cavity 61 in a reverse relationship to the arrangement shown in FIG. 3. FIG. 4 is a plan view of the package 6 where the top ceramic layer is not shown.

An input terminal A and an output terminal B are arranged as signal terminals on a surface of the transmission filter chip 2 in a reverse relationship to the arrangement shown in FIG. 3, and an input terminal C and an output terminal D are arranged as signal terminals on a surface of the reception filter chip 3 in a reverse relationship to the arrangement shown in FIG. 3. These signal terminals are respectively coupled via wires 4 with a plurality of wiring patterns formed on the substrate and around the cavity 61.

The antenna terminal ANT, transmission side signal terminal Tx, reception side signal terminal Rx, and a plurality of ground terminals GND, which serve as external connection terminals, are respectively formed as side electrodes on a side surface of the substrate. These terminals are respectively connected via the wiring patterns and the wires 4 to the corresponding signal terminals of the transmission filter chip 2 and reception filter chip 3.

In FIG. 4, the transmission side signal terminal Tx and the reception side signal terminal Rx are arranged in a reverse relationship to the arrangement shown in FIG. 3.

The reception side signal terminal Rx is connected via a reception side output signal wiring pattern 75 and wire 4 with the output terminal D of the reception filter chip 3, and the transmission side signal terminal Tx is connected via a transmission side input signal wiring pattern 85 and wire 4 with the input terminal A of the transmission filter chip 2.

As described above, the antenna duplexer shown in FIG. 3 and the antenna duplexer shown in FIG. 4 are configured in a reverse relationship with respect to positions of the terminals and the wiring patterns relative to a border line between the transmission filter chip 2 and the reception filter chip 3 indicated by a broken line in the drawings, and thereby applicable to two types of design specifications where two terminals of an external circuit to be connected to the transmission side signal terminal Tx and the reception side signal terminal Rx are in a reverse relationship.

Patent Document 1: JP-A-11-340781

Patent Document 2: JP-A-2000-307383

### DISCLOSURE OF THE INVENTION

Problem to be Solved by the Invention

However, although the antenna duplexer shown in FIG. 3 and the antenna duplexer shown in FIG. 4 have the electrically entirely same circuit, two types of packages with different wiring patterns need be prepared in order to be applicable to two types of design specifications for positions of the transmission side signal terminal Tx and the reception side signal terminal Rx. This also requires two types of production equipments such as printing screens or molds, and has been causing a problem of an increased production cost.

Accordingly, an object of the present invention is to provide an electronic device such as a laminate ceramic electronic device, and a package structure thereof, applicable to two types of design specifications for positions of signal terminals by using a common package.

Means for Solving the Problem

In a laminate ceramic electronic device of the present invention, a package for mounting at least one circuit chip includes a substrate formed by laminating a plurality of ceramic layers. The substrate is provided with a circuit chip mounting portion having at least one circuit chip mounted thereon, and a plurality of external connection terminals for connecting the circuit chip mounted on the circuit chip mounting portion to an external circuit. A plurality of wiring patterns extending from the plurality of external connection terminals toward the circuit chip mounting portion are formed on a surface of one ceramic layer of the substrate. An end of each of the wiring patterns can be wire-bonded to a corresponding signal terminal of the circuit chip on the circuit chip mounting portion.

Two signal terminals of the circuit chip mounted on the circuit chip mounting portion are arranged either in a first arrangement or in a second arrangement. A wiring pattern for connecting each of the signal terminals together with a corresponding external connection terminal has two branch wiring portions divergingly extending from the external connection terminal toward a position of one signal terminal in the first arrangement and toward a position of the other signal terminal in the second arrangement, respectively. An end of either one of the branch wiring portions is wire-bonded with either one of the signal terminals.

According to the above laminate ceramic electronic device of the present invention, because either one of the branch wiring portions of any one of the wiring patterns extends close to each of the signal terminals, an end of the branch wiring portion can be wire-bonded to the signal terminal even if positions where the two signal terminals are to be placed are changed from one arrangement to the other arrangement in accordance with design specifications for arrangement of the plurality of signal terminals of the circuit chip mounted on the circuit chip mounting portion.

Therefore, it is unnecessary to prepare two types of packages in accordance with design specifications for positions of the signal terminals of the circuit chip, and possible to provide a common package.

Specifically, the circuit chip mounting portion can mount one or more circuit chips having incorporated therein a transmission filter and a reception filter for constituting an antenna duplexer. An input terminal A and an output terminal B of the transmission filter and an input terminal C and an output terminal D of the reception filter are arranged in either one of first and second arrangements where the terminals are in a reverse relationship relative to a border line between a transmission filter incorporating part and a reception filter incorporating part. A wiring pattern, which connects the input terminal A of the transmission filter together with a transmission side signal terminal Tx in the first arrangement, has two branch wiring portions divergingly extending from the transmission side signal terminal Tx toward a position of the input terminal A of the transmission filter in the first arrangement and toward a position of the output terminal D of the reception filter in the second arrangement, respectively. A wiring pattern, which connects the output terminal D of the reception filter together with a reception side signal terminal Rx in the first arrangement, has two branch wiring portions divergingly extending from the reception side signal terminal Rx toward a position of the output terminal D of the reception filter in the first arrangement and toward a position of the input terminal A of the transmission filter in the second arrangement, respectively.

According to the specific configuration, because either one of the branch wiring portions of either one of the wiring patterns extends close to the input terminal A of the transmission filter to be connected with the transmission side signal terminal Tx or to the output terminal D of the reception filter to be connected with the reception side signal terminal Rx, an end of the branch wiring portion can be wire-bonded to the input terminal A or the output terminal D even if positions of the transmission side signal terminal Tx and reception side signal terminal Rx are changed to the reverse positions, and positions of the input terminal A and output terminal B of the transmission filter and the input terminal C and output terminal D of the reception filter are changed from one arrangement to the other arrangement accordingly in the case of two design specifications being given where the positions of the transmission side signal terminal Tx and reception side signal terminal Rx to be disposed on the substrate are in a reverse relationship.

Therefore, it is unnecessary to prepare two types of packages in accordance with design specifications for positions of the transmission side signal terminal Tx and reception side signal terminal Rx, and possible to provide a common package.

Specifically, the input terminal A of the transmission filter and the output terminal D of the reception filter are arranged at diagonal positions in a rectangular surface area defined by a surface of the transmission filter incorporating part and a surface of the reception filter incorporating part.

According to the specific configuration, a length of the two branch wiring portions of the wiring pattern for connecting the input terminal A of the transmission filter together with the transmission side signal terminal Tx, or for connecting the output terminal D of the reception filter together with the reception side signal terminal Rx, can be shortened to a necessary minimum.

Further specifically, a plurality of wiring patterns extending from an antenna terminal ANT, the transmission side signal terminal Tx, the reception side signal terminal Rx, and a plurality of ground terminals GND, respectively, are formed on the surface of the one ceramic layer and around the circuit chip mounting portion symmetrically about a center line passing through the antenna terminal and the circuit chip mounting portion.

According to the specific configuration, even if positions of the input terminal A and output terminal B of the transmission filter, the input terminal C and output terminal D of the reception filter, and a plurality of ground terminals G are changed to the reverse positions, these signal terminals can be wire-bonded to the plurality of wiring patterns on the substrate through a shortest path.

### EFFECT OF THE INVENTION

The laminate ceramic electronic device of the present invention and the package used for the same are applicable to two types of design specifications for positions of signal terminals by using a common package. This allows manufacture of packages using common production equipment, reducing a production cost. Moreover, production management and inventory management become easy because two types of packages are reduced to one.

### BEST MODE FOR CARRYING OUT THE INVENTION

The present invention embodied in an antenna duplexer will be specifically described below with reference to the drawings.

As shown in FIG. 7, an antenna duplexer of the present invention includes an antenna terminal ANT to be connected to an antenna, a transmission side signal terminal Tx to be connected to a transmitting circuit, and a reception side signal terminal Rx to be connected to a receiving circuit. The antenna terminal ANT is connected to the transmission side signal terminal Tx via a transmission filter chip 2 including a surface acoustic wave device, and connected to the reception side signal terminal Rx via a reception filter chip 3 including a surface acoustic wave device.

A phase-matching strip line 9 for phase rotation is interposed between the antenna terminal ANT and the reception filter chip 3 to match the phases between the transmission filter chip 2 and the reception filter chip 3.

FIG. 8 shows a laminate structure of the antenna duplexer enclosed in a package. A laminate ceramic package 1 is constructed by recessing a surface of a substrate 10 formed by laminating a plurality of ceramic layers 12-16 to provide a cavity 11, and further covering the cavity 11 with a lid 17. The transmission filter chip 2 and the reception filter chip 3 are arranged on the bottom surface of the cavity 11 in a side-by-side relationship.

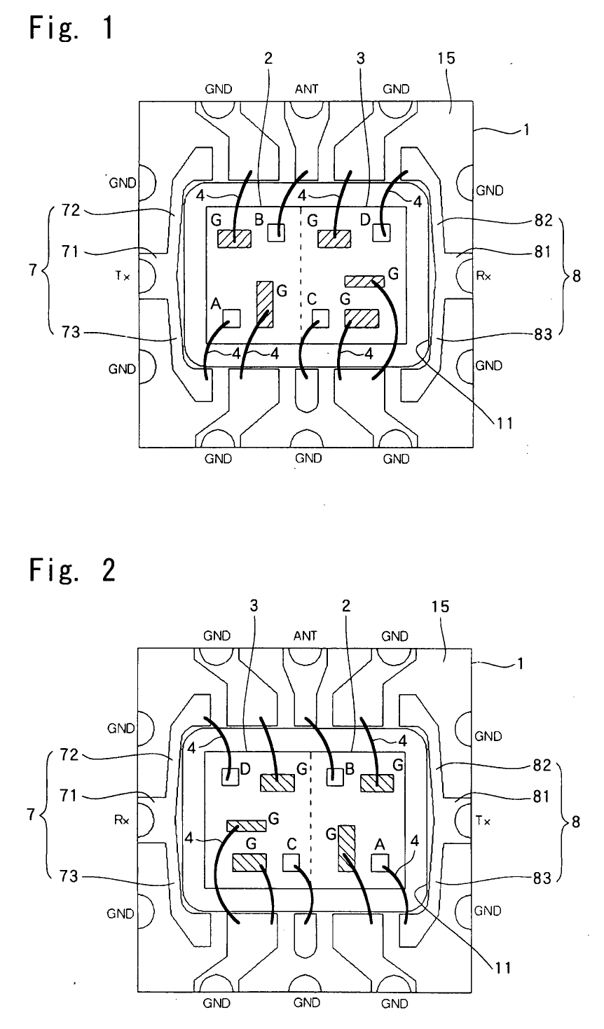

FIG. 1 is a plan view of the package 1 where the lid 17 and a ceramic layer 16, the top layer (first layer), are not shown. As illustrated, an input terminal A, an output terminal B and two ground terminals G are disposed on a surface of the transmission filter chip 2, and an input terminal C, an output terminal D and two ground terminals G are disposed on a surface of the reception filter chip 3. These signal terminals are respectively coupled via wires 4 with a plurality of wiring patterns formed on a second ceramic layer 15 and around the cavity 11.

The input terminal A of the transmission filter chip 2 and the output terminal D of the reception filter chip 3 are arranged at diagonal positions in a rectangular surface of the transmission filter chip 2 and reception filter chip 3. This improves the isolation characteristics.

The antenna terminal ANT, transmission side signal terminal Tx, reception side signal terminal Rx, and a plurality of ground terminals GND, which serve as external connection terminals, are respectively formed as side electrodes on a side surface of the package 1. These terminals are respectively connected via the wiring patterns and the wires 4 to the corresponding signal terminals of the transmission filter chip 2 and reception filter chip 3.

The plurality of wiring patterns on the second ceramic layer 15 of the package 1 extend toward the cavity 11 from the antenna terminal ANT, transmission side signal terminal Tx, reception side signal terminal Rx, and plurality of ground terminals GND. A first wiring pattern 7 extending from the transmission side signal terminal Tx includes a common wiring portion 71 having the base end thereof connected with the transmission side signal terminal Tx, and two branch wiring portions 72, 73 divergingly extending from the top end of the common wiring portion 71. Ends of both branch wiring portions 72, 73 reach opposed positions of two corners of the transmission filter chip 2. A second wiring pattern 8 extending from the reception side signal terminal Rx includes a common wiring portion 81 having the base end thereof connected with the reception side signal terminal Rx, and two branch wiring portions 82, 83 divergingly extending from the top end of the common wiring portion 81. Ends of both branch wiring portions 82, 83 reach opposed positions of two corners of the reception filter chip 3.

These wiring patterns are formed symmetrically about a center line passing through the antenna terminal ANT and a center portion of the package 1.

Out of the two branch wiring portions 72, 73 of the first wiring pattern 7, one branch wiring portion 73, which extends close to the input terminal A of the transmission filter chip 2, has an end thereof connected with the input terminal A via a wire 4.

Out of the two branch wiring portions 82, 83 of the second wiring pattern 8, one branch wiring portion 82, which extends close to the output terminal D of the reception filter chip 3, has an end thereof connected with the output terminal D via a wire 4.

FIG. 2 is a plan view of the package 1 in another antenna duplexer enclosed in a package, where the lid and the top ceramic layer are not shown. The antenna duplexer has a specification where positions of the transmission side signal terminal Tx and reception side signal terminal Rx to be disposed in the package 1 are set in a reverse relationship to those of the antenna duplexer shown in FIG. 1. Accordingly, the arrangement of the transmission filter chip 2 and reception filter chip 3 mounted in the cavity 11 of the package 1 and the arrangement of the signal terminals on each of the filter chips are set in a reverse relationship to the arrangement shown in FIG. 1.

In contrast, the package 1 shown in FIG. 2 is common to the antenna duplexer shown in FIG. 1. The wiring patterns formed on the surface of the second ceramic layer 15 and wiring patterns formed on other ceramic layers are the same.

However, the transmission side signal terminal Tx of the package 1 shown in FIG. 1 is used as the reception side signal terminal Rx in the package 1 of FIG. 2, and the reception side signal terminal Rx of the package 1 shown in FIG. 1 is used as the transmission side signal terminal Tx in the package 1 of FIG. 2.

As shown in FIG. 2, out of the two branch wiring portions 72, 73 of the first wiring pattern 7, the other branch wiring portion 72, which extends close to the output terminal D of the reception filter chip 3, has an end thereof connected with the output terminal D via a wire 4.

Out of the two branch wiring portions 82, 83 of the second wiring pattern 8, the other branch wiring portion 83, which extends close to the input terminal A of the transmission filter chip 2, has an end thereof connected with the input terminal A via a wire 4.

Therefore, as shown in FIG. 1 and FIG. 2, the package 1 can be commonly used for two types of antenna duplexers in the case of manufacturing the two types of antenna duplexers having specifications where positions of the transmission side signal terminal Tx and reception side signal terminal Rx to be disposed in the package 1 are in a reverse relationship.

This needs only one production equipment although two are conventionally necessary for manufacture of two types of antenna duplexers, allowing reduction of a production cost.

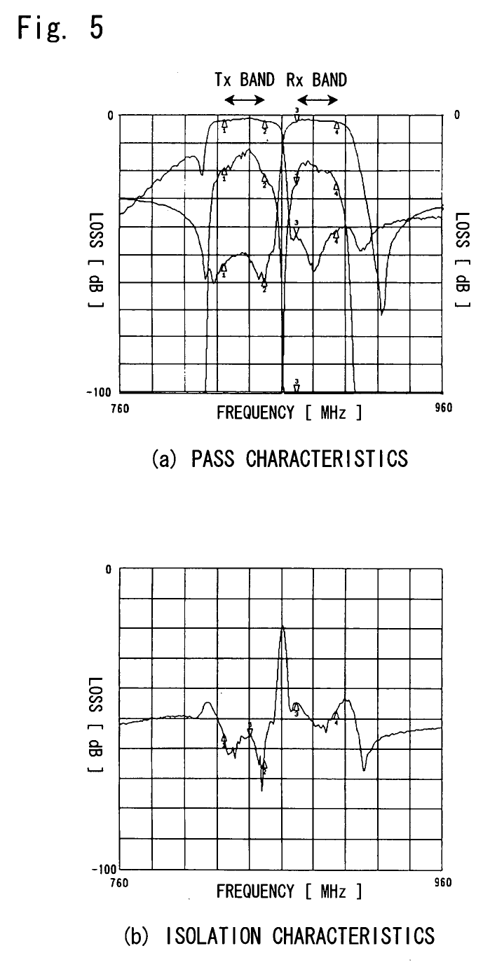

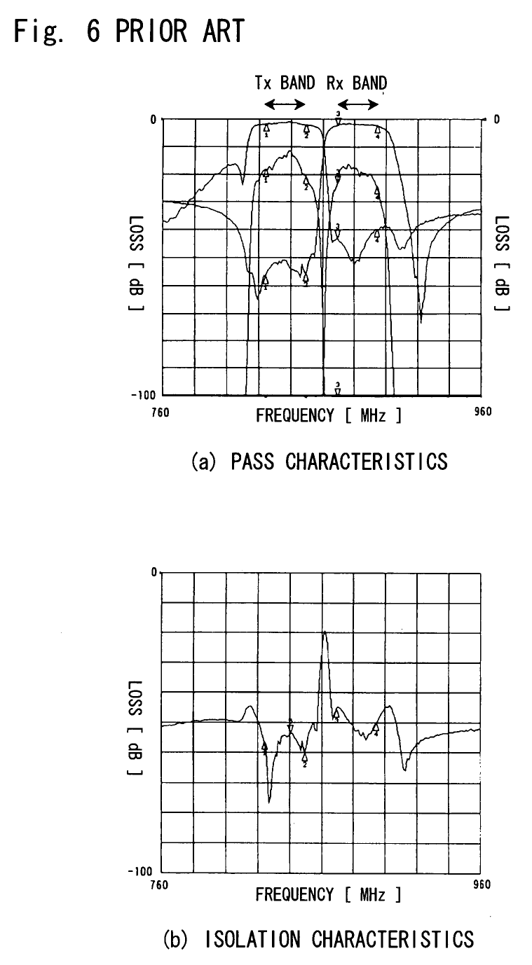

FIG. 5 illustrates graphs showing the pass characteristics and isolation characteristics of the antenna duplexer of the present invention using the common package 1 shown in FIG. 1, and FIG. 6 illustrates graphs showing the pass characteristics and isolation characteristics of the conventional antenna duplexer using the individual package 5 shown in FIG. 3.

It is apparent from FIG. 5 and FIG. 6 that the antenna duplexer of the present invention also can provide the pass characteristics and isolation characteristics equivalent to those of the conventional antenna duplexer.

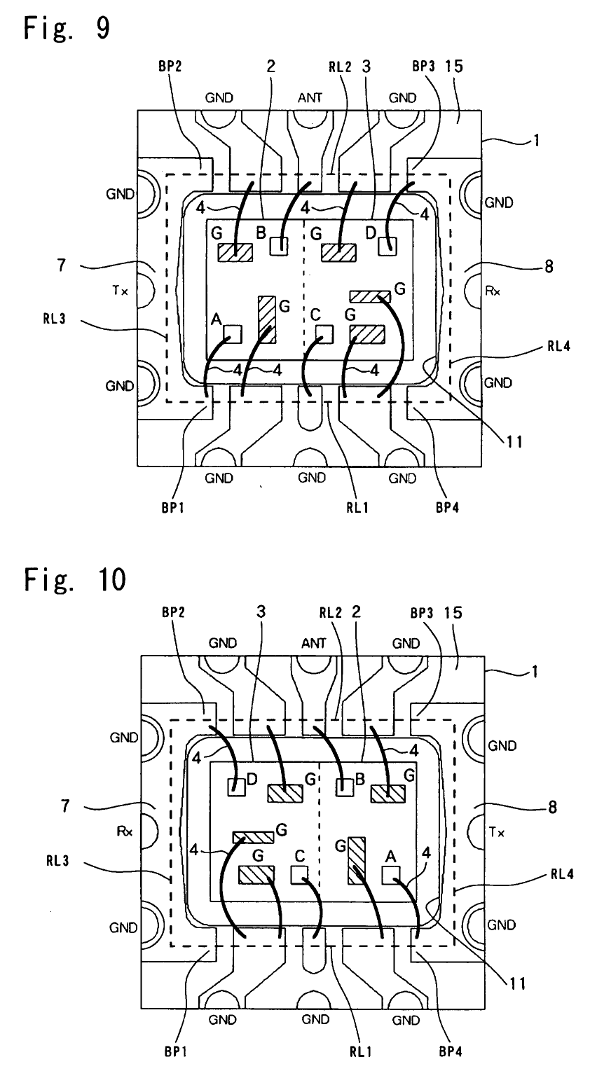

The shape of the first wiring pattern 7 and second wiring pattern 8 is not limited to the above embodiment. For example, the shape shown in FIG. 9 and FIG. 10 is also possible. FIG. 9 and FIG. 10 are different from FIG. 1 and FIG. 2, respectively, only in the shape of the first wiring pattern 7 and second wiring pattern 8, but the same in other respects.

A specific description will be given below with reference to FIG. 9 and FIG. 10. The same reference numeral is given to the same part as in FIG. 1 and FIG. 2, with no repetition of description unless otherwise specified.

Five bonding pad portions are aligned along each of two sides RL1, RL2 out of four sides RL1, RL2, RL3, RL4 of a square (indicated by a dot line) surrounding the circuit chip mounting portion, although the circuit chip mounting portion is out of view because it is covered with the transmission filter 2 and the reception filter chip 3 mounted thereon.

In the arrangement of the filter chips of FIG. 9, a first bonding pad portion BP1 connected via a wire 4 with the input terminal A of the transmission filter chip 2 is provided along a first side RL1, and a third bonding pad portion BP3 connected via a wire 4 with the output terminal D of the reception filter chip 3 is provided along a second side RL2.

In the arrangement of the filter chips of FIG. 10, a second bonding pad portion BP2 connected via a wire 4 with the output terminal D of the reception filter chip 3 is provided along the second side RL2, and a fourth bonding pad portion BP4 connected via a wire 4 with the input terminal A of the transmission filter chip 2 is provided along the first side RL1.

Further, the first wiring pattern 7 connects the first bonding pad portion BP1 with the second bonding pad portion BP2, and the second wiring pattern 8 connects the third bonding pad portion BP3 with the fourth bonding pad portion BP4.

The present invention is not limited to the foregoing embodiment in construction but can be modified variously within the technical scope as set forth in the appended claims.

For example, the first wiring pattern 7 and/or the second wiring pattern 8 may be formed, not only on the surface of the second ceramic layer 15, but also on a surface of a lower ceramic layer, with an end of the wiring pattern being connected by a via hole with a pad on the surface of the second ceramic layer 15, and the pad being wire-bonded with a signal terminal of a filter chip.

Although the two circuit chips, transmission filter chip 2 and reception filter chip 3, are mounted on the package 1, a single circuit chip incorporating a transmission filter and a reception filter may be mounted.

The substrate is not limited to the embodiment in which a plurality of ceramic layers are laminated. For example, a substrate layer including glass epoxy resin or the like may be used as a material to provide a substrate including the substrate layer or a plurality of such layers.

### BRIEF DESCRIPTION OF THE DRAWINGS

[FIG. 1] is a plan view showing an antenna duplexer of the present invention, where the top ceramic layer is not shown.

[FIG. 2] is a plan view similarly showing an antenna duplexer of the present invention with different terminal arrangement.

[FIG. 3] is a plan view similarly showing a conventional antenna duplexer.

[FIG. 4] is a plan view similarly showing a conventional antenna duplexer with different terminal arrangement.

[FIG. 5] illustrates graphs showing the pass characteristics and isolation characteristics of the antenna duplexer of the present invention.

[FIG. 6] illustrates graphs showing the pass characteristics and isolation characteristics of the conventional antenna duplexer.

[FIG. 7] is a block diagram showing a circuit configuration of the antenna duplexer.

[FIG. 8] is a sectional view showing a laminate structure of the antenna duplexer of the present invention.

[FIG. 9] is a plan view showing another embodiment of the present invention.

[FIG. 10] is a plan view showing an antenna duplexer of the present invention with terminal arrangement different from that of FIG. 9.

### EXPLANATION OF NUMERALS

1 package

11 cavity

2 transmission filter chip

3 reception filter chip

7 first wiring pattern

71 common wiring portion

72 branch wiring portion

73 branch wiring portion

8 second wiring pattern

81 common wiring portion

82 branch wiring portion

83 branch wiring portion

ANT antenna terminal

Tx transmission side signal terminal

Rx reception side signal terminal

1. A package for an electronic device, comprising a substrate comprising one or more substrate layers, the substrate being provided with a circuit chip mounting portion capable of mounting one or more circuit chips having a first filter and a second filter incorporated therein, and with a plurality of external connection terminals for connecting a circuit chip mounted on the circuit chip mounting portion to an external circuit, the substrate having a surface of one substrate layer provided with a plurality of bonding pad portions to be connected by wire bonding with a signal terminal of the circuit chip on the circuit chip mounting portion, and formed with a plurality of wiring patterns extending from the external connection terminals toward the bonding pad portions,
wherein the first filter and the second filter are arranged either in a first arrangement or in a second arrangement, and the plurality of bonding pad portions are aligned along a first side and a second side out of four sides of a square surrounding the circuit chip mounting portion,
wherein a first bonding pad portion to be wire-bonded with an input terminal of the first filter in the first arrangement and a second bonding pad portion to be wire-bonded with an output terminal of the second filter in the second arrangement are provided at different sides of the first side and the second side, and a first wiring pattern connects the first bonding pad portion with the second bonding pad portion,
wherein a third bonding pad portion to be wire-bonded with an output terminal of the second filter in the first arrangement and a fourth bonding pad portion to be wire-bonded with an input terminal of the first filter in the second arrangement are provided at different sides of the first side and the second side, and a second wiring pattern connects the third bonding pad portion with the fourth bonding pad portion.

2. A package for an electronic device, comprising a substrate formed by laminating a plurality of ceramic layers, the substrate being provided with a circuit chip mounting portion for mounting at least one circuit chip, and with a plurality of external connection terminals for connecting the circuit chip mounted on the circuit chip mounting portion to an external circuit, the substrate having a surface of one ceramic layer formed with a plurality of wiring patterns extending from the plurality of external connection terminals toward the circuit chip mounting portion, each of the wiring patterns being capable of having an end thereof wire-bonded to a corresponding signal terminal of the circuit chip on the circuit chip mounting portion,
wherein two signal terminals of the circuit chip mounted on the circuit chip mounting portion are arranged either in a first arrangement or in a second arrangement, and a wiring pattern for connecting each of the signal terminals together with a corresponding external connection terminal has two branch wiring portions divergingly extending from the external connection terminal toward a position of one signal terminal in the first arrangement and toward a position of the other signal terminal in the second arrangement, respectively.

3. The package for an electronic device according to claim 2, wherein the circuit chip mounting portion is capable of mounting one or more circuit chips having incorporated therein a transmission filter and a reception filter for constituting an antenna duplexer, and an input terminal A and an output terminal B of the transmission filter and an input terminal C and an output terminal D of the reception filter are arranged in either one of first and second arrangements where the terminals are in a reverse relationship relative to a border line between a transmission filter incorporating part and a reception filter incorporating part, wherein a wiring pattern for connecting the input terminal A of the transmission filter together with a transmission side signal terminal Tx in the first arrangement has two branch wiring portions divergingly extending from the transmission side signal terminal Tx toward a position of the input terminal A of the transmission filter in the first arrangement and toward a position of the output terminal D of the reception filter in the second arrangement, respectively, and a wiring pattern for connecting the output terminal D of the reception filter together with a reception side signal terminal Rx in the first arrangement has two branch wiring portions divergingly extending from the reception side signal terminal Rx toward a position of the output terminal D of the reception filter in the first arrangement and toward a position of the input terminal A of the transmission filter in the second arrangement, respectively.

4. The package for an electronic device according to claim 1 or claim 3, wherein a plurality of wiring patterns extending from an antenna terminal ANT, the transmission side signal terminal Tx, the reception side signal terminal Rx, and a plurality of ground terminals GND, respectively, are formed on the surface of the one ceramic layer and around the circuit chip mounting portion symmetrically about a center line passing through the antenna terminal and the circuit chip mounting portion.

5. An electronic device comprising a substrate comprising one or more substrate layers, the substrate being provided with a circuit chip mounting portion having mounted thereon one or more circuit chips having a first filter and a second filter incorporated therein, and with a plurality of external connection terminals for connecting the circuit chip to an external circuit, the substrate having a surface of one substrate layer provided with a plurality of bonding pad portions connected by wire bonding with a signal terminal of the circuit chip, and formed with a plurality of wiring patterns extending from the external connection terminals toward the bonding pad portions,
wherein the first filter and the second filter are arranged either in a first arrangement or in a second arrangement, and the plurality of bonding pad portions are aligned along a first side and a second side out of four sides of a square surrounding the circuit chip mounting portion,
wherein a first bonding pad portion wire-bonded with an input terminal of the first filter in the first arrangement and a second bonding pad portion wire-bonded with an output terminal of the second filter in the second arrangement are provided at different sides of the first side and the second side, and a first wiring pattern connects the first bonding pad portion with the second bonding pad portion,
wherein a third bonding pad portion wire-bonded with an output terminal of the second filter in the first arrangement and a fourth bonding pad portion wire-bonded with an input terminal of the first filter in the second arrangement are provided at different sides of the first side and the second side, and a second wiring pattern connects the third bonding pad portion with the fourth bonding pad portion.

6. A laminate ceramic electronic device comprising a substrate formed by laminating a plurality of ceramic layers, the substrate being provided with a circuit chip mounting portion having at least one circuit chip mounted thereon, and with a plurality of external connection terminals for connecting the circuit chip mounted on the circuit chip mounting portion to an external circuit, the substrate having a surface of one ceramic layer formed with a plurality of wiring patterns extending from the plurality of external connection terminals toward the circuit chip mounting portion, each of the wiring patterns having an end thereof wire-bonded to a corresponding signal terminal of the circuit chip on the circuit chip mounting portion,
wherein two signal terminals of the circuit chip mounted on the circuit chip mounting portion are arranged either in a first arrangement or in a second arrangement, and a wiring pattern for connecting each of the signal terminals together with a corresponding external connection terminal has two branch wiring portions divergingly extending from the external connection terminal toward a position of one signal terminal in the first arrangement and toward a position of the other signal terminal in the second arrangement, respectively, either one of the branch wiring portions having an end thereof wire-bonded with either one of the signal terminals.

7. The laminate ceramic electronic device according to claim 6, wherein the circuit chip mounting portion mounts a circuit chip having incorporated therein a transmission filter and a reception filter for constituting an antenna duplexer, and an input terminal A and an output terminal B of the transmission filter and an input terminal C and an output terminal D of the reception filter are arranged in either one of first and second arrangements where the terminals are in a reverse relationship relative to a border line between a transmission filter incorporating part and a reception filter incorporating part, wherein a wiring pattern for connecting the input terminal A of the transmission filter together with a transmission side signal terminal Tx in the first arrangement has two branch wiring portions divergingly extending from the transmission side signal terminal Tx toward a position of the input terminal A of the transmission filter in the first arrangement and toward a position of the output terminal D of the reception filter in the second arrangement, respectively, and a wiring pattern for connecting the output terminal D of the reception filter together with a reception side signal terminal Rx in the first arrangement has two branch wiring portions divergingly extending from the reception side signal terminal Rx toward a position of the output terminal D of the reception filter in the first arrangement and toward a position of the input terminal A of the transmission filter in the second arrangement, respectively.

8. The laminate ceramic electronic device according to claim 7, wherein the input terminal A of the transmission filter and the output terminal D of the reception filter are arranged at diagonal positions in a rectangular surface area defined by a surface of the transmission filter incorporating part and a surface of the reception filter incorporating part.

9. The laminate ceramic electronic device according to claim 7 or claim 8, wherein a plurality of wiring patterns extending from an antenna terminal ANT, the transmission side signal terminal Tx, the reception side signal terminal Rx, and a plurality of ground terminals GND, respectively, are formed on the surface of the one ceramic layer and around the circuit chip mounting portion symmetrically about a center line passing through the antenna terminal and the circuit chip mounting portion.
